(19) United States
(12) Patent Application Publication
(10) Pub. No.: US 2026/0336032 A1
(43) Pub. Date: Oct. 29, 2026

(54) PROCESSING METHOD, DEVICE CHIP MANUFACTURING METHOD, AND LASER PROCESSING APPARATUS

(71) Applicant: DISCO CORPORATION, Tokyo (JP)

(72) Inventors: Atsushi MAEDA, Tokyo (JP); Keiji NOMARU, Tokyo (JP); Shin TABATA, Tokyo (JP); Wakana ONOE, Tokyo (JP)

(21) Appl. No.: 19/577,718

(22) Filed: Mar. 25, 2026

(30) Foreign Application Priority Data
Mar. 31, 2025 (JP) 2025-059113
Mar. 10, 2026 (JP) 2026-037714
Mar. 18, 2026 (JP) 2026-044726

(51) Int. Cl. B23K 26/362; B23K 26/0622; B23K 101/40; H10P 50/24; H10P 58/00

(52) U.S. Cl. CPC B23K 26/362; B23K 26/0622; H10P 50/24; H10P 58/00; B23K 2101/40

(57) ABSTRACT

A method for processing a workpiece includes: forming a film layer on a workpiece; forming a mask by irradiating the film layer with light having a wavelength such that the light passes through the workpiece and resonates with a material constituting the film layer to form an opening in the film layer; and etching the workpiece through the mask.

### CROSS-REFERENCE TO RELATED APPLICATION(S)

The present application claims priority to and incorporates by reference the entire contents of Japanese Patent Applications No. 2025-059113 filed on Mar. 31, 2025, No. 2026-037714 filed on Mar. 10, 2026, and No. 2026-044726 filed on Mar. 18, 2026.

### BACKGROUND

The present invention relates to a processing method, a device chip manufacturing method, and a laser processing apparatus.

Conventional etching of a workpiece uses a mask formed by stacking a film layer on the workpiece and forming an opening in the film layer with a laser processing apparatus, as an etching mask (e.g., see JP 2016-207737 A).

However, when the opening is formed by the laser processing apparatus, the workpiece is also slightly processed during laser processing of the film layer. When the workpiece is processed, there is a possibility that minute irregularities are formed on the laser-processed surface of the workpiece and the irregularities may be formed larger due to etching.

In addition, the film layer needs to have a thickness sufficient to protect the workpiece during etching, but it takes time to perform laser processing on the film layer having the sufficient thickness in order to form the opening, and improvement is strongly desired.

### SUMMARY

A method for processing a workpiece according to one aspect of the present disclosure includes: forming a film layer on a workpiece; forming a mask by irradiating the film layer with light having a wavelength such that the light passes through the workpiece and resonates with a material constituting the film layer to form an opening in the film layer; and etching the workpiece through the mask.

A method for manufacturing a device chip according to another aspect of the present disclosure includes: forming a film layer on a wafer on which a plurality of lines to be divided and a plurality of device regions defined by the lines to be divided are set; forming a mask by irradiating the film layer with light having a wavelength such that the light passes through the wafer and resonates with a material constituting the film layer to form an opening in the film layer; etching the wafer through the mask; removing the mask from the wafer; and dividing the wafer along the lines to be divided to form device chips.

A laser processing apparatus according to still another aspect of the present disclosure is to process a film layer of a workpiece on which the film layer is stacked, and includes: a holding unit configured to hold the workpiece on which the film layer is stacked; an oscillator; a condenser configured to focus a laser beam emitted from the oscillator on the film layer stacked on the workpiece held by the holding unit; and a moving unit configured to move a focal point where the laser beam is focused on the workpiece by the condenser relative to the workpiece held by the holding unit. A wavelength of the laser beam focused on the film layer by the condenser is a wavelength such that the laser beam passes through the workpiece and resonates with a material constituting the film layer.

### BRIEF DESCRIPTION OF THE DRAWINGS

FIG. 1 is a perspective view of an exemplary configuration of a laser processing apparatus according to a first embodiment;

FIG. 2 is a perspective view schematically illustrating a workpiece to be processed by the laser processing apparatus illustrated in FIG. 1;

FIG. 3 is a diagram schematically illustrating a configuration of a laser beam unit and the like of the processing apparatus illustrated in FIG. 1;

FIG. 4 is a flowchart illustrating a procedure of a device chip manufacturing method according to the first embodiment;

FIG. 5 is a partially cross-sectional side view schematically illustrating a film layer forming step of the device chip manufacturing method illustrated in FIG. 4;

FIG. 6 is a partially cross-sectional side view schematically illustrating a mask forming step of the device chip manufacturing method illustrated in FIG. 4;

FIG. 7 is an enlarged cross-sectional view illustrating a main part of the workpiece after the mask forming step of the device chip manufacturing method illustrated in FIG. 4;

FIG. 8 is an enlarged cross-sectional view illustrating the main part of the workpiece during a removal step of the device chip manufacturing method illustrated in FIG. 4;

FIG. 9 is an enlarged cross-sectional view illustrating the main part of the workpiece after the removal step of the device chip manufacturing method illustrated in FIG. 4;

FIG. 10 is an enlarged cross-sectional view illustrating the main part of the workpiece during an etching step of the device chip manufacturing method illustrated in FIG. 4;

FIG. 11 is an enlarged cross-sectional view illustrating the main part of the workpiece after the etching step of the device chip manufacturing method illustrated in FIG. 4;

FIG. 12 is a partially cross-sectional side view schematically illustrating a mask removing step of the device chip manufacturing method illustrated in FIG. 4;

FIG. 13 is a perspective view schematically illustrating the workpiece after a device forming step of the device chip manufacturing method illustrated in FIG. 4;

FIG. 14 is a perspective view schematically illustrating the workpiece after a division step of the device chip manufacturing method illustrated in FIG. 4;

FIG. 15 is a perspective view schematically illustrating a workpiece to be processed by the laser processing apparatus and a device chip manufacturing method according to a second embodiment;

FIG. 16 is a perspective view schematically illustrating a state of the workpiece illustrated in FIG. 15, supported by a frame;

FIG. 17 is a flowchart illustrating a procedure of the device chip manufacturing method according to the second embodiment;

FIG. 18 is a partially cross-sectional side view schematically illustrating the mask forming step of the device chip manufacturing method illustrated in FIG. 17;

FIG. 19 is an enlarged cross-sectional view illustrating a main part of the workpiece after the removal step of the device chip manufacturing method illustrated in FIG. 17; and

FIG. 20 is an enlarged cross-sectional view illustrating the main part of the workpiece after the etching step of the device chip manufacturing method illustrated in FIG. 17.

### DETAILED DESCRIPTION

Modes (embodiments) for carrying out the present disclosure will be described in detail with reference to the drawings. It is noted that the present invention is not limited to the contents described in the following embodiments. In addition, component elements described below include those readily conceivable by those skilled in the art and those substantially equivalent. Furthermore, configurations described below may be appropriately combined. Still furthermore, various omissions, substitutions, or modifications of the configurations may be made without departing from the gist of the present invention.

### First Embodiment

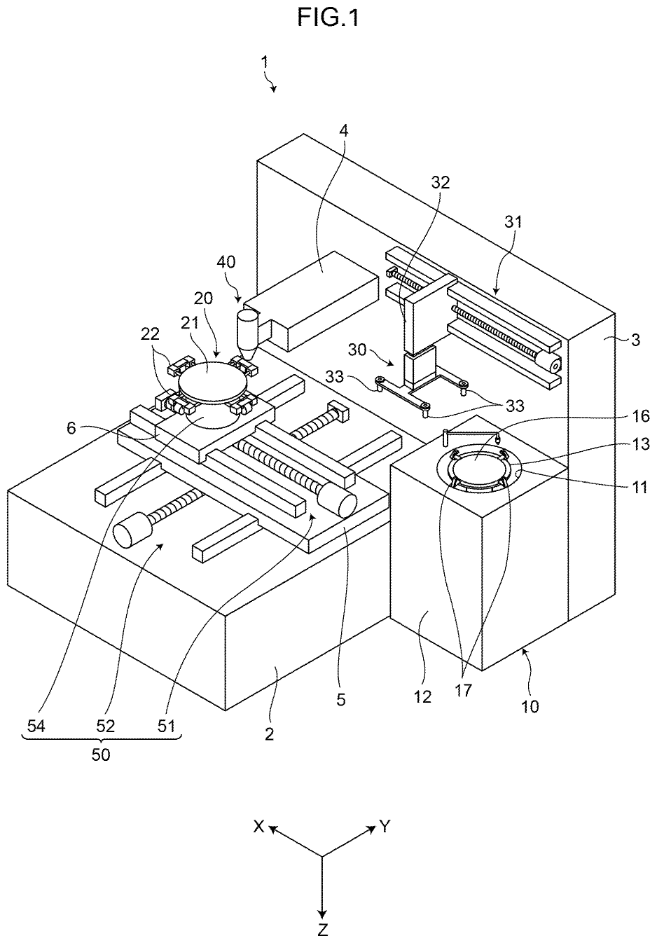

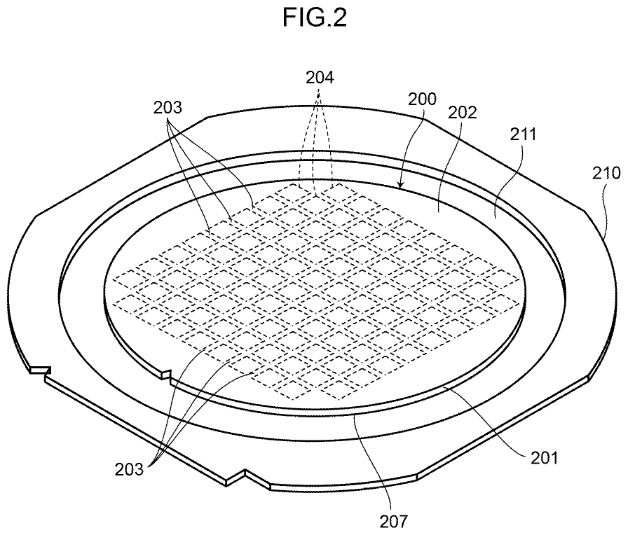

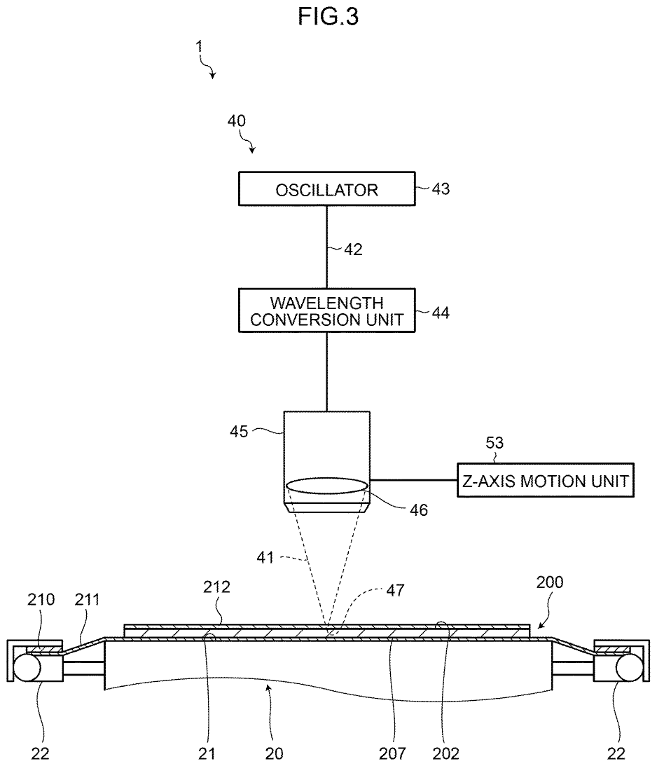

A laser processing apparatus according to a first embodiment of the present disclosure will be described with reference to the drawings. FIG. 1 is a perspective view of an exemplary configuration of the laser processing apparatus according to the first embodiment. FIG. 2 is a perspective view schematically illustrating a workpiece to be processed by the laser processing apparatus illustrated in FIG. 1. FIG. 3 is a diagram schematically illustrating a configuration of a laser beam unit and the like of the processing apparatus illustrated in FIG. 1.

### Workpiece

The laser processing apparatus 1 illustrated in FIG. 1 according to the first embodiment is a processing apparatus that stacks a film layer 212 (illustrated in FIG. 3) on a front surface 202 of a workpiece 200 illustrated in FIG. 2 and processes the film layer 212 on the front surface 202 of the workpiece 200 on which the film layer 212 is stacked. The workpiece 200 to be processed by the laser processing apparatus 1 illustrated in FIG. 1 according to the first embodiment is a wafer such as a disk-shaped semiconductor device wafer or optical device wafer using silicon (Si), germanium (Ge), aluminum oxide (Al2O3), gallium arsenide (GaAs), indium tin oxide (ITO), gallium nitride (GaN), or silicon carbide (SiC) as a substrate 201. Note that in the first embodiment, the substrate 201 of the workpiece 200 is made of silicon.

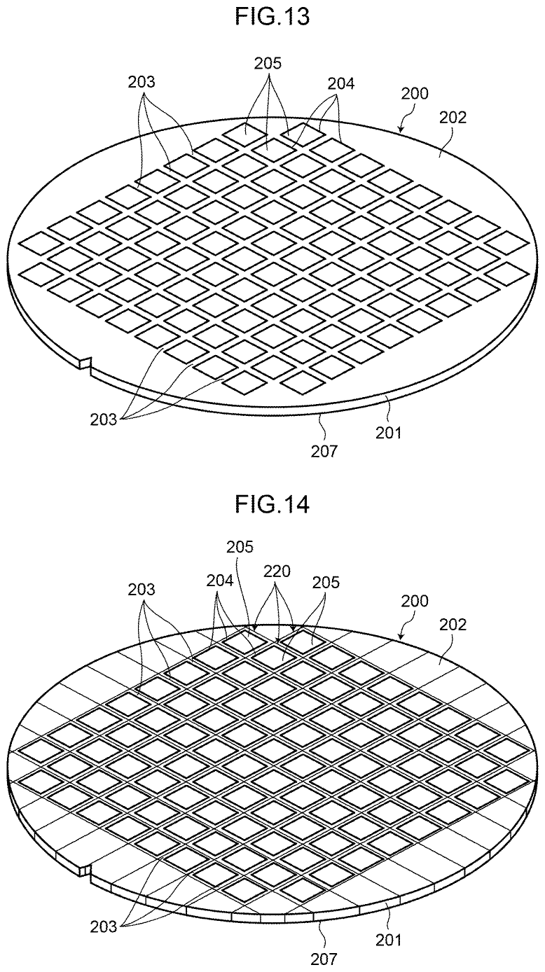

In the workpiece 200, a plurality of planned division lines 203 that intersect each other is set on the front surface 202, and a device region 204 (represented by a broken line in FIG. 2) that is defined by the planned division lines 203, set on the front surface 202, is formed. In the first embodiment, the workpiece 200 is a wafer before a device 205 (illustrated in FIG. 13) is formed in the device region 204 on the front surface 202, i.e., a wafer on which the device 205 is not formed. In this way, in the first embodiment, the plurality of planned division lines 203 and a plurality of the device regions 204 defined by the plurality of planned division lines 203 are set on the front surface 202 of the workpiece 200.

The device 205 includes, for example, an integrated circuit such as an integrated circuit (IC) or a large scale integration (LSI), an image sensor such as a charge coupled device (CCD) or a complementary metal oxide semiconductor (CMOS), a memory (semiconductor storage device), a micro electro mechanical systems (MEMS), a capacitor, or a metal-oxide-semiconductor field-effect transistor (MOSFET).

Note that in the first embodiment, in the workpiece 200, the substrate 201 is made of silicon, and the device 205 formed in each of the device regions 204 includes MEMS, a capacitor, or MOSFET. In this way, in the first embodiment, the device 205 formed in the device region 204 of the workpiece 200 has a trench structure in which a recessed portion 206 (illustrated in FIG. 11) is formed as a trench.

In the first embodiment, as illustrated in FIG. 2, a tape 211 having a disk shape with a diameter larger than an outer diameter of the workpiece 200 and including a frame 210 applied to an outer edge portion of the tape 211 is applied to the center of a back surface 207 on the back side of the front surface 202 to support the workpiece 200 in an opening of the frame 210. In the first embodiment, the devices 205, each of which includes the MEMS, the capacitor, or the MOSFET, are formed in the device regions 204, and then the workpiece 200 is cut along the planned division lines 203, and divided into individual device chips 220 (illustrated in FIG. 14). Note that each of the device chips 220 includes a part of the substrate 201, and the device 205.

### Laser Processing Apparatus

A processing method according to the first embodiment is partially performed by the laser processing apparatus 1 illustrated in FIG. 1. The laser processing apparatus 1 illustrated in FIG. 1 is a processing apparatus that irradiates the film layer 212 stacked on the front surface 202 of the workpiece 200 with a pulsed laser beam 41 (corresponding to light and pulse laser beam). As illustrated in FIG. 1, the laser processing apparatus 1 includes a coating/cleaning unit 10 that forms the film layer 212 on the front surface 202 of the workpiece 200, a holding unit 20 that has a holding surface 21 holding the workpiece 200 on which the film layer 212 is stacked, a transfer unit 30, a laser beam irradiation unit 40, a moving unit 50, and an imaging unit and a control unit, both of which are not illustrated.

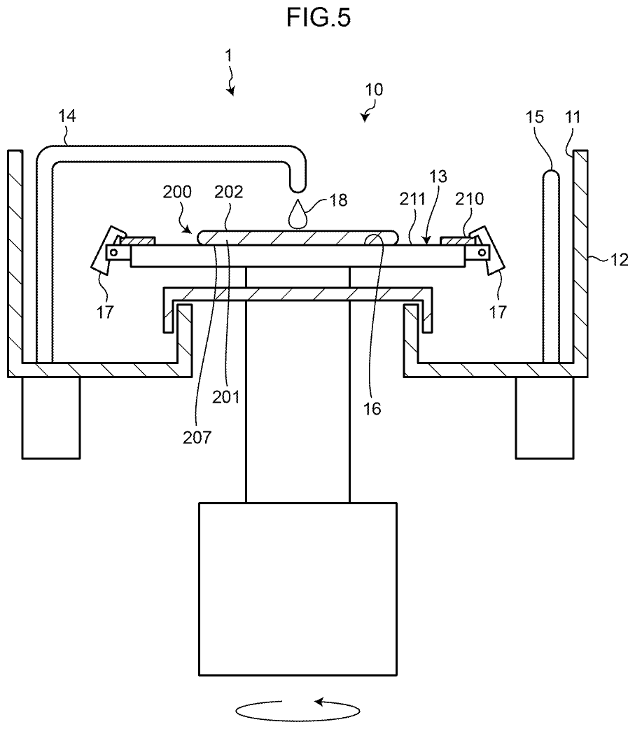

The coating/cleaning unit 10 is arranged adjacent in an X-axis direction parallel to a horizontal direction to an apparatus body 2 on which the holding unit 20 is installed. The coating/cleaning unit 10 includes a box-shaped unit body 12 that is provided with an upper circular opening 11, a spinner table 13 that is accommodated in a unit body 12, a coating nozzle 14 (illustrated in FIG. 5), and a cleaning nozzle 15 (illustrated in FIG. 5).

The spinner table 13 has a disk shape and holds the workpiece 200 on a holding surface 16 being parallel to the horizontal direction. The holding surface 16 is formed of a porous material such as porous ceramic, and is connected to a vacuum suction source, which is not illustrated, via a vacuum suction path, which is not illustrated. The spinner table 13 holds the workpiece 200 mounted on the holding surface 16, in a suction manner. A plurality of clampers 17 that clamps the frame 210 supporting the workpiece 200 in the opening is arranged around the spinner table 13.

The spinner table 13 is rotated about an axis orthogonal to the holding surface 21 and parallel to a vertical direction (hereinafter, referred to as a Z-axis direction) by a rotation drive source which is not illustrated. The spinner table 13 is arranged at a position in the unit body 12 where the holding surface 16 is exposed through the opening 11 of the unit body 12.

The coating nozzle 14 and the cleaning nozzle 15 are accommodated in the unit body 12, and are each arranged to be swingable by a rotation drive source, which is not illustrated, around a base end portion arranged on an outer peripheral side of the spinner table 13. Each of the coating nozzle 14 and the cleaning nozzle 15 is swung by the rotation drive source to move between a position where a front end faces the center of the workpiece 200 held on the spinner table 13 and a position where the front end is positioned on the outer peripheral side of the workpiece 200.

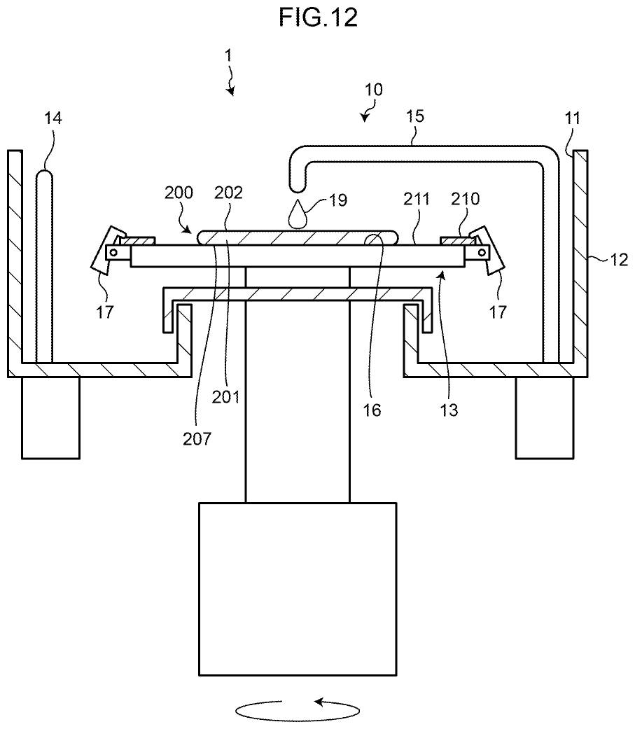

The coating nozzle 14 supplies, from the front end, a liquid protective film agent 18 (illustrated in FIG. 5) that forms the film layer 212, onto the center of the workpiece 200. The cleaning nozzle 15 supplies, from the front end, a liquid cleaner 19 (illustrated in FIG. 12) that removes the film layer 212 and cleans the front surface 202 of the workpiece 200, onto the center of the workpiece 200.

Note that the protective film agent 18 supplied by the coating nozzle 14 includes, for example, a material including a water-soluble resin such as polyvinyl alcohol (PVA) or polyvinylpyrrolidone (PVP), a material including an organic substance, a material including an organic substance having a carbon-carbon triple bond (structural formula: —C≡C—), a material including an organic substance having at least one of a carbon-carbon double bond and a carbon-oxygen double bond, a material including an organic substance having at least one of a carbon-carbon bond and a carbon-oxygen bond, a resin including a coloring material (pigment or dye), a resin including cycloparaphenylene, or a resin containing water.

The coating/cleaning unit 10 holds a side of the back surface 207 of the workpiece 200 on the holding surface 16 of the spinner table 13, in the suction manner, and clamps the frame 210 with the clampers 17 around the spinner table 13. The coating/cleaning unit 10 applies the liquid protective film agent 18 from a coating nozzle 34 to the center of the front surface 202 of the workpiece 200 while rotating the spinner table 13 about the axis. Then, the protective film agent 18 applied to the front surface 202 of the workpiece 200 is spread to the outer edge of the workpiece 200 by a centrifugal force generated by the rotation of the spinner table 13, covers the entire front surface 202 of the workpiece 200, and is gradually dried by being exposed to the atmosphere by the rotation of the spinner table 13.

The coating/cleaning unit 10 dries the protective film agent 18 covering the entire front surface 202 of the workpiece 200 to form the film layer 212 illustrated in FIG. 3, on the entire front surface 202 of the workpiece 200. The film layer 212 includes a water-soluble resin such as polyvinyl alcohol (PVA) or polyvinylpyrrolidone (PVP), a material including an organic substance, an organic substance having a carbon-carbon triple bond (structural formula: —C≡C—), an organic substance having at least one of a carbon-carbon double bond and a carbon-oxygen double bond, an organic substance having at least one of a carbon-carbon bond and a carbon-oxygen bond, a resin including a coloring material (pigment or dye), or a resin including cycloparaphenylene. The film layer 212 has resistance to an etching gas converted into plasma.

In addition, the coating/cleaning unit 10 holds the side of the back surface 207 of the workpiece 200 on the holding surface 16 of the spinner table 13, in the suction manner, and clamps the frame 210 with the clampers 17 around the spinner table 13. The coating/cleaning unit 10 supplies the cleaner 19 for removing the film layer 212 in liquid form, from the cleaning nozzle 15 to the center of the front surface 202 of the workpiece 200 while rotating the spinner table 13 about the axis. Then, the cleaner 19 supplied to the front surface 202 of the workpiece 200 is spread to the outer edge side of the workpiece 200 by the centrifugal force generated by the rotation of the spinner table 13, flows on the front surface 202 of the workpiece 200, and removes the film layer 212 from the front surface 202 of the workpiece 200.

The holding unit 20 has a disk shape and holds the workpiece 200 on the holding surface 21 being parallel to a horizontal direction. The holding surface 21 is formed of porous ceramic or the like, and is connected to a vacuum suction source, which is not illustrated, via a vacuum suction path, which is not illustrated. The holding unit 20 holds the workpiece 200 mounted on the holding surface 21, in a suction manner. Around the holding unit 20, a plurality of clampers 22 that clamps the frame 210 supporting the workpiece 200 in an opening is arranged.

Furthermore, the holding unit 20 is rotated about an axis parallel to the Z-axis direction orthogonal to the holding surface 21 by a rotary motion unit 54 of the moving unit 50. The holding unit 20 is moved together with the rotary motion unit 54, in an X-axis direction by an X-axis motion unit 51 of the moving unit 50 and in a Y-axis direction parallel to the horizontal direction and orthogonal to the X-axis direction by a Y-axis motion unit 52. The holding unit 20 is moved by the moving unit 50 between a processing region below the laser beam irradiation unit 40 and a carry-in/out region away from below the laser beam irradiation unit 40 where the workpiece 200 is carried in and carried out.

The transfer unit 30 transfers the workpiece 200 from the spinner table 13, to the holding unit 20 in the carry-in/out region. The transfer unit 30 is lifted/lowered in a Z-axis direction by a lifting/lowering unit 32, and is moved in an X-axis direction by a transfer unit moving unit 31 provided on a vertical wall 3 extending from an end of the apparatus body 2 in a Y-axis direction. The lifting/lowering unit 32 is moved in the X-axis direction by the transfer unit moving unit 31. The transfer unit 30 has a lower end provided with a suction holder 33 that holds the frame 210 in a suction manner.

The transfer unit 30 holds the frame 210 at a lower end of the suction holder 33 in a suction manner, is lifted/lowered in the Z-axis direction by the lifting/lowering unit 32, is moved in the X-axis direction by the transfer unit moving unit 31, thus transferring the workpiece 200 from the spinner table 13 to the holding unit 20 in the carry-in/out region.

The laser beam irradiation unit 40 is a unit that irradiates the workpiece 200 held by the holding unit 20 with the pulsed laser beam 41 (illustrated in FIG. 3). In the first embodiment, as illustrated in FIG. 1, the laser beam irradiation unit 40 is partially supported at a front end of a beam-shaped support member 4 that has a base end fixed to the vertical wall 3 and that extends in parallel with the Y-axis direction.

In the first embodiment, as illustrated in FIG. 3, the laser beam irradiation unit 40 includes an oscillator 43 for oscillation and emission of a pulsed laser beam 42, a wavelength conversion unit 44, and a condenser 45. In the first embodiment, the oscillator 43 is a so-called ultrashort pulse laser that oscillates and emits the laser beam 42 having a wavelength of 1030 nm and a pulse width ranging from femtosecond to picosecond. In the first embodiment, the oscillator 43 is an oscillator for oscillation of a Yb:YAG laser.

The wavelength conversion unit 44 is a unit that converts the wavelength of the laser beam 42 emitted from the oscillator 43. In the first embodiment, the wavelength conversion unit 44 may be configured by, for example, a parametric amplifier that converts the wavelength of light to a longer wavelength by using an optical parametric effect. In addition, the wavelength conversion unit 44 may include a difference frequency generator that generates a difference frequency for light having the longer wavelength after conversion by the parametric amplifier to make the wavelength longer, or a harmonic generator that generates a harmonic for the light to make the wavelength shorter.

In the first embodiment, the wavelength conversion unit 44 constituted by an optical parametric amplifier enables formation of a wide range of wavelengths, and conversion of the wavelength of the laser beam 42 to an optimum wavelength according to the film layer 212 by the same device. Furthermore, in the first embodiment, the oscillator 43 including the ultrashort pulse laser also enables output of the laser beam 41 having a wavelength converted, as an ultrashort pulse. The laser beam 41 having a pulse width of the ultrashort pulse enables as much reduction of the thermal influence on the workpiece 200 as possible, and reduction of dross, burrs, cracks, and the like generated in the workpiece 200, thus improving processing accuracy.

In addition, in the present disclosure, the wavelength conversion unit 44 may include a periodically poled nonlinear optical crystal, instead of the optical parametric amplifier.

The condenser 45 focuses the laser beam 41 emitted from the oscillator 43 and having a wavelength converted by the wavelength conversion unit 44, on the film layer 212 stacked on the front surface 202 of the workpiece 200 held by the holding unit 20.

The condenser 45 includes a condenser lens 46 that focuses the laser beam 41 on the film layer 212 stacked on the front surface 202 of the workpiece 200 held on the holding surface 21 of the holding unit 20.

Furthermore, in the first embodiment, the wavelength of the laser beam 41 having the wavelength converted by the wavelength conversion unit 44 and focused on the film layer 212 on the front surface 202 of the workpiece 200 by the condenser 45 is a wavelength such that the laser beam 41 passes through the substrate 201 of the workpiece 200 and resonates with the material constituting the film layer 212. Furthermore, in the first embodiment, the wavelength of the laser beam 41 having the wavelength converted by the wavelength conversion unit 44 and focused on the film layer 212 on the front surface 202 of the workpiece 200 by the condenser 45 is a wavelength that resonates with one of molecular vibration of the material constituting the film layer 212 and electron transition between energy levels of the material constituting the film layer 212.

In the present disclosure, when the substrate 201 of the workpiece 200 is silicon (Si), germanium (Ge), aluminum oxide (Al2O3), or gallium arsenide (GaAs) (hereinafter, silicon (Si), germanium (Ge), aluminum oxide (Al2O3), or gallium arsenide (GaAs) is referred to as a material 1), the film layer 212 may use a water-soluble resin, a material including an organic substance, an organic substance having a carbon-carbon triple bond, an organic substance having at least one of a carbon-carbon double bond and a carbon-oxygen double bond, or an organic substance having at least one of a carbon-carbon single bond and a carbon-oxygen single bond.

In the present disclosure, when the substrate 201 of the workpiece 200 is made of aluminum oxide (Al2O3), gallium arsenide (GaAs), indium tin oxide (ITO), gallium nitride (GaN), or silicon carbide (SiC) (hereinafter, aluminum oxide (Al2O3), gallium arsenide (GaAs), indium tin oxide (ITO), gallium nitride (GaN), or silicon carbide (SiC) is referred to as a material 2), the film layer 212 may use a resin including a coloring material (pigment or dye) or a resin including cycloparaphenylene.

Note that in the present disclosure, when the substrate 201 of the workpiece 200 includes the material 1, and when the film layer 212 includes the water-soluble resin such as polyvinyl alcohol (PVA) or polyvinylpyrrolidone (PVP), the wavelength of the laser beam 41 having the wavelength converted by the wavelength conversion unit 44 and focused on the film layer 212 on the front surface 202 of the workpiece 200 by the condenser 45 is 2.7 μm or more and 3.5 μm or less. In this case, the film layer 212 resonates with stretching vibration of OH group of the water-soluble resin, which is molecular vibration. In this way, when the film layer 212 is made of the water-soluble resin, the resonance of the film layer 212 corresponds to the stretching vibration of OH group of the water-soluble resin as the molecular vibration. Furthermore, in the present disclosure, when the substrate 201 of the workpiece 200 includes the material 1, and when the film layer 212 contains water, the wavelength of the pulse laser beam 41 having the wavelength converted by the wavelength conversion unit 44 and focused on the film layer 212 on the front surface 202 of the workpiece 200 by the condenser 45 is 2.7 μm or more and 3.5 μm or less. In this case, the film layer 212 resonates with the molecular vibration of water. In this way, when the film layer 212 contains water, the resonance of the film layer 212 corresponds to the resonance of the molecular vibration of water.

Furthermore, in the present disclosure, when the substrate 201 of the workpiece 200 includes the material 1, and when the film layer 212 includes the material containing an organic substance, the wavelength of the laser beam 41 having the wavelength converted by the wavelength conversion unit 44 and focused on the film layer 212 on the front surface 202 of the workpiece 200 by the condenser 45 is 3.1 μm or more and 3.6 μm or less. In this case, the film layer 212 resonates with stretching vibration of CH group of the material containing an organic substance, which is molecular vibration. In this way, when the film layer 212 is made of the material containing an organic substance, the resonance of the film layer 212 corresponds to the stretching vibration of the CH group as the molecular vibration.

Furthermore, in the present disclosure, when the substrate 201 of the workpiece 200 includes the material 1, and when the film layer 212 includes the organic substance having a carbon-carbon triple bond (structural formula: —C≡C—), the wavelength of the laser beam 41 having the wavelength converted by the wavelength conversion unit 44 and focused on the film layer 212 on the front surface 202 of the workpiece 200 by the condenser 45 is 4.0 μm or more and 5.0 μm or less. In this case, the film layer 212 resonates with stretching vibration of the triple bond, which is molecular vibration. In this way, when the film layer 212 is made of the organic substance having a carbon-carbon triple bond (structural formula: —C≡C—), the resonance of the film layer 212 corresponds to the stretching vibration of the triple bond as the molecular vibration.

Furthermore, in the present disclosure, when the substrate 201 of the workpiece 200 includes the material 1, and when the film layer 212 includes the organic substance having at least one of a carbon-carbon double bond and a carbon-oxygen double bond, the wavelength of the laser beam 41 having the wavelength converted by the wavelength conversion unit 44 and focused on the film layer 212 on the front surface 202 of the workpiece 200 by the condenser 45 is 5.0 μm or more and 7.0 μm or less. In this case, the film layer 212 resonates with stretching vibration of the double bond, which is molecular vibration. In this way, when the film layer 212 is made of the organic substance having at least one of a carbon-carbon double bond and a carbon-oxygen double bond, the resonance of the film layer 212 corresponds to the stretching vibration of the double bond as the molecular vibration.

Furthermore, in the present disclosure, when the substrate 201 of the workpiece 200 includes the material 1, and when the film layer 212 includes the organic substance having at least one of a carbon-carbon single bond and a carbon-oxygen single bond, the wavelength of the laser beam 41 having the wavelength converted by the wavelength conversion unit 44 and focused on the film layer 212 on the front surface 202 of the workpiece 200 by the condenser 45 is 7.0 μm or more and 20.0 μm or less. In this case, the film layer 212 resonates with stretching vibration of the carbon-carbon bond or the carbon-oxygen bond, which is molecular vibration. In this way, when the film layer 212 includes the organic substance having at least one of a carbon-carbon bond and a carbon-oxygen bond, the resonance of the film layer 212 corresponds to the stretching vibration of the carbon-carbon bond or the carbon-oxygen bond as the molecular vibration.

Furthermore, in the present disclosure, when the substrate 201 of the workpiece 200 includes the material 2, and when the film layer 212 includes the coloring material (pigment or dye), the wavelength of the laser beam 41 is 360 nm or more and 830 nm or less. In this case, the film layer 212 resonates with ππ* electronic transition, which is the electron transition between energy levels. In this way, when the film layer 212 is made of the resin including a coloring material (pigment or dye), the resonance of the film layer 212 corresponds to the ππ* electronic transition, which is the electron transition between energy levels.

Furthermore, in the present disclosure, when the substrate 201 of the workpiece 200 includes the material 2, and when the film layer 212 includes cycloparaphenylene, the wavelength of the laser beam 41 is 1.0 μm or more and 1.1 μm or less. In this case, the film layer 212 resonates with the ππ* electronic transition, which is the electron transition between energy levels. In this way, when the film layer 212 is made of the resin containing cycloparaphenylene, the resonance of the film layer 212 corresponds to the ππ* electronic transition, which is the electron transition between energy levels.

Note that in the first embodiment, the substrate 201 of the workpiece 200 includes the material 1, and the film layer 212 uses the water-soluble resin, a material including an organic substance, an organic substance having a carbon-carbon triple bond, an organic substance having at least one of a carbon-carbon double bond and a carbon-oxygen double bond, or an organic substance having at least one of a carbon-carbon single bond and a carbon-oxygen single bond. Furthermore, in the present disclosure, in a modification, when the substrate 201 of the workpiece 200 includes the material 2, the film layer 212 may use the resin including a coloring material (pigment or dye) or the resin including cycloparaphenylene.

Furthermore, in the present disclosure, for a wavelength having transparency to the workpiece 200 and a wavelength resonating with the material of the film layer 212, an Er:YAG laser is used, when the substrate 201 of the workpiece 200 includes the material 1 and the film layer 212 includes the water-soluble resin or the material including an organic substance. In the present invention, when the oscillator 43 is capable of emitting a pulse laser beam having a wavelength that passes through the workpiece 200 and resonates with the material of the film layer 212, the laser beam irradiation unit 40 need not include the wavelength conversion unit 44. In that case, the laser beam irradiation unit 40 can be made simpler and less expensive than a configuration including the wavelength conversion unit 44. For example, when the substrate 201 of the workpiece 200 is made of material 1 and the film layer 212 is made of a material containing a water-soluble resin, an Er:YAG laser is used as the oscillator 43. Since an Er:YAG laser oscillator is known to provide a relatively high output, the film layer made of the water-soluble resin containing OH groups can be removed efficiently. An Er-doped fluoride glass fiber laser oscillator may be used instead of the Er:YAG laser oscillator. Since the Er-doped fluoride glass fiber laser oscillator is capable of emitting a laser beam having a shorter pulse width (for example, several hundred nanoseconds) than that of the Er:YAG laser oscillator, thermal effects in removing the film layer 212 can be reduced, and dross, burrs, cracks, and the like generated in the workpiece can be reduced, thereby improving processing accuracy.

Furthermore, in the present disclosure, for the wavelength having transparency to the workpiece 200 and the wavelength resonating with the material of the film layer 212, a CO2 laser is used when the substrate 201 of the workpiece 200 includes the material 1 and the film layer 212 includes the organic substance having at least one of a carbon-carbon single bond and a carbon-oxygen single bond, and a YAG laser or the Yb:YAG laser is used when the substrate 201 of the workpiece 200 includes the material 2 and the film layer 212 includes cycloparaphenylene, for irradiation of the workpiece 200 with the laser beam 41 without using the wavelength conversion unit 44.

The moving unit 50 relatively moves the laser beam irradiation unit 40 and the holding unit 20 in the X-axis direction and the Y-axis direction, and about the axis parallel to the Z-axis direction to move a focal point 47 (illustrated in FIG. 3) where the laser beam 41 is focused on the workpiece 200 by the condenser 45 relative to the workpiece 200 held by the holding unit 20. The X-axis direction and the Y-axis direction are parallel to the holding surface 21. The X-axis direction is a so-called processing feed direction in which the holding unit 20 is fed for processing when the laser processing apparatus 1 performs laser processing on the workpiece 200. The Y-axis direction is orthogonal to the X-axis direction, and is a so-called indexing feed direction in which indexing feed of the holding unit 20 is performed when the laser processing apparatus 1 performs laser processing on the workpiece 200.

The moving unit 50 includes the X-axis motion unit 51 that is a processing feed unit moving the holding unit 20 in the X-axis direction, the Y-axis motion unit 52 that is an indexing feed unit moving the holding unit 20 in the Y-axis direction, a Z-axis motion unit 53 (illustrated in FIG. 3) that moves the condenser lens 46 included in the condenser 45 of the laser beam irradiation unit 40, in the Z-axis direction, and the rotary motion unit 54 that rotates the holding unit 20 about the axis parallel to the Z-axis direction.

The Y-axis motion unit 52 is a unit that performs relative indexing feed of the holding unit 20 and the laser beam irradiation unit 40. In the first embodiment, the Y-axis motion unit 52 is installed on the apparatus body 2 of the laser processing apparatus 1. The Y-axis motion unit 52 supports a moving plate 5 supporting the X-axis motion unit 51, in a movable manner in the Y-axis direction.

The X-axis motion unit 51 is a unit that relatively feeds the holding unit 20 and the laser beam irradiation unit 40, for processing. The X-axis motion unit 51 is installed on the moving plate 5. The X-axis motion unit 51 supports a second moving plate 6 that supports the rotary motion unit 54 rotating the holding unit 20 about the axis parallel to the Z-axis direction, in a movable manner in the X-axis direction.

The X-axis motion unit 51, the Y-axis motion unit 52, and the Z-axis motion unit 53 include known ball screws that are provided to be axially rotatable, known pulse motors that axially rotate the ball screws, and known guide rails that support the moving plate 5 and 6 in a movable manner in the X-axis direction or the Y-axis direction and support the condenser lens 46 in a movable manner in the Z-axis direction. The rotary motion unit 54 includes a motor and the like that rotate the holding unit 20 about the axis.

In addition, the laser processing apparatus 1 includes an X-axis direction position detection unit, which is not illustrated, for detecting a position of the holding unit 20 in the X-axis direction, a Y-axis direction position detection unit, which is not illustrated, for detecting a position of the holding unit 20 in the Y-axis direction, and a Z-axis direction position detection unit for detecting a position of the condenser lens 46 included in the laser beam irradiation unit 40, in the Z-axis direction. Each of the position detection units outputs a detection result to the control unit.

The imaging unit images the workpiece 200 held by the holding unit 20. The imaging unit includes an image sensor, such as a charge coupled device (CCD) image sensor or a complementary MOS (CMOS) image sensor, that images the workpiece 200 held by the holding unit 20. In the first embodiment, the imaging unit images the workpiece 200, obtains an image for alignment to align the workpiece 200 and the laser beam irradiation unit 40, and outputs the obtained image to the control unit.

The control unit controls each of the above component elements of the laser processing apparatus 1 to cause the laser processing apparatus 1 to perform a laser processing operation on the workpiece 200. Note that the control unit is a computer that includes an arithmetic processing device including a microprocessor such as a central processing unit (CPU), a storage device including a memory such as a read only memory (ROM) or a random access memory (RAM), and an input/output interface device. The arithmetic processing device of the control unit performs arithmetic processing according to a computer program stored in the storage device, and outputs a control signal for controlling the laser processing apparatus 1 to each of the above component elements of the laser processing apparatus 1 via the input/output interface device to implement the function of the control unit.

The control unit is connected to a display unit that includes a liquid crystal display device or the like displaying a processing operation status, an image, or the like, and an input unit, which is not illustrated, used when an operator registers processing content information or the like. The input unit includes at least one of a touch screen provided on the display unit and an external input device such as a keyboard.

### Device Chip Manufacturing Method

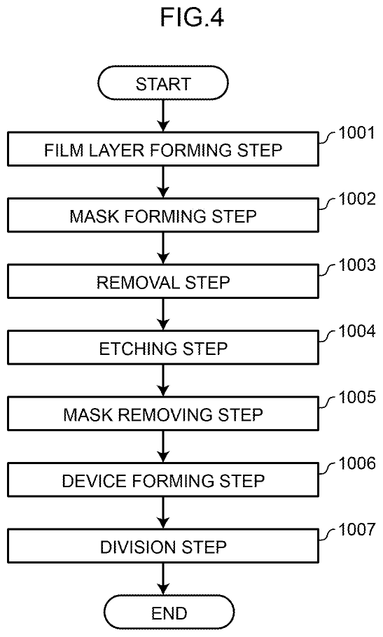

Next, a device chip manufacturing method according to the first embodiment will be described. FIG. 4 is a flowchart illustrating a procedure of the device chip manufacturing method according to the first embodiment. The device chip manufacturing method according to the first embodiment is a method of manufacturing the device chips 220 by forming the devices 205, each of which includes the MEMS, the capacitor, or the MOSFET, in each of the device regions 204 of the workpiece 200 illustrated in FIG. 1, and cutting the workpiece 200 along the planned division lines 203.

As illustrated in FIG. 4, the device chip manufacturing method according to first embodiment includes a film layer forming step 1001, a mask forming step 1002, a removal step 1003, an etching step 1004, a mask removing step 1005, a device forming step 1006, and a division step 1007.

### Film Layer Forming Step

FIG. 5 is a partially cross-sectional side view schematically illustrating the film layer forming step of the device chip manufacturing method illustrated in FIG. 4. The film layer forming step 1001 is a step of forming the film layer 212 on the front surface 202 of the workpiece 200 illustrated in FIG. 1. In the film layer forming step 1001, the center of the tape 211 is applied to the back surface 207 of the workpiece 200 to support the workpiece 200 in the opening of the frame 210.

In the first embodiment, in the film layer forming step 1001, the laser processing apparatus 1 holds the back surface 207 of the workpiece 200 on the spinner table 13 of the coating/cleaning unit 10 in the suction manner, and clamps the frame 210 with the clampers 17. In the first embodiment, in the film layer forming step 1001, as illustrated in FIG. 5, the laser processing apparatus 1 applies the protective film agent 18 from the end of the coating nozzle 14, to the center of the front surface 202 of the workpiece 200 while rotating the spinner table 13 of the coating/cleaning unit 10 about the axis center, and dries the protective film agent 18 to form the film layer 212 over the entire front surface 202 of the workpiece 200. Note that in the first embodiment, the film layer 212 including the water-soluble resin is formed.

### Mask Forming Step

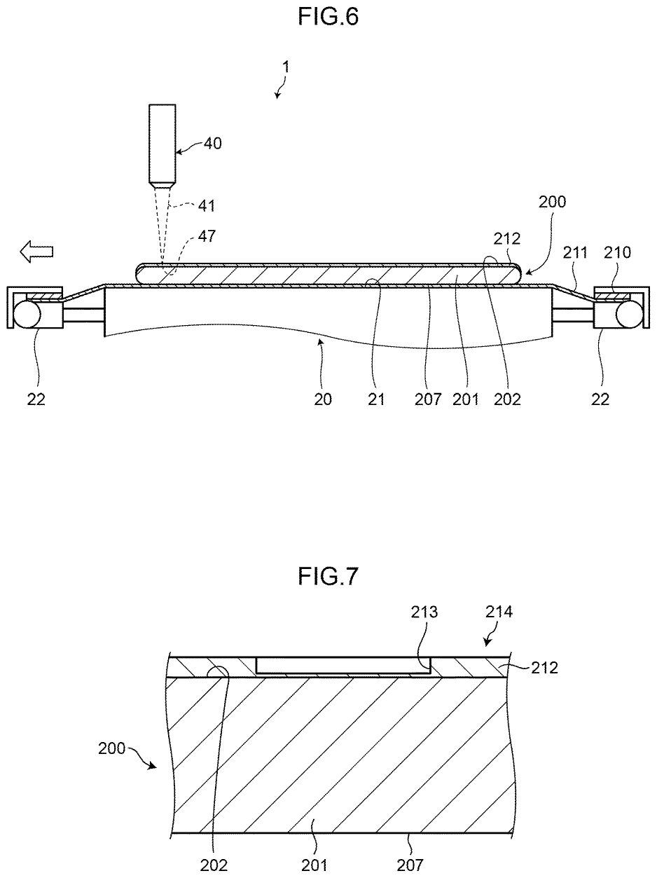

FIG. 6 is a partially cross-sectional side view schematically illustrating the mask forming step of the device chip manufacturing method illustrated in FIG. 4. FIG. 7 is an enlarged cross-sectional view illustrating a main part of the workpiece after the mask forming step of the device chip manufacturing method illustrated in FIG. 4. The mask forming step 1002 is a step of irradiating the film layer 212 corresponding to the device regions 204 with the laser beam 41 that is light having a wavelength such that the light passes through the substrate 201 of the workpiece 200 and resonates with the material constituting the film layer 212, forming an opening 213 in the film layer 212, and forming a mask 214 used in the etching step 1004. Note that the film layer 212 corresponding to the device regions 204 is a position where the film layer 212 overlaps the device regions 204.

In the first embodiment, in the mask forming step 1002, the laser processing apparatus 1 transfers the workpiece 200 on which the film layer 212 is formed by using the transfer unit 30 to the holding unit 20 in the carry-in/out region. In the first embodiment, in the mask forming step 1002, the laser processing apparatus 1 holds the back surface 207 of the workpiece 200 on the holding surface 21 of the holding unit 20 in the suction manner, and clamps the frame 210 with the clampers 22.

In the first embodiment, in the mask forming step 1002, the laser processing apparatus 1 moves the holding unit 20 toward the processing region by using the moving unit 50, and images the workpiece 200 by the imaging unit, for alignment. In the first embodiment, in the mask forming step 1002, as illustrated in FIG. 6, the laser processing apparatus 1 sets the focal point 47 of the laser beam 41 to the film layer 212, and applies the laser beam 41 to a position overlapping the recessed portion 206 of the device 205 formed in each device region 204 of the film layer 212 while relatively moving the workpiece 200 held by the holding unit 20 and the laser beam irradiation unit 40 by using the moving unit 50. Note that in the first embodiment, the film layer 212 on the front surface 202 of the workpiece 200 is irradiated with the laser beam 41 having a wavelength of 3 μm.

Furthermore, in the mask forming step 1002 in the first embodiment, the laser beam 41 to irradiate the film layer 212 has a pulse width that is set shorter than a time required for one pulse of the laser beam 41 with which the film layer 212 is irradiated to thermally diffuse outside of a beam spot of the laser beam 41 on the film layer 212. Note that the time required to thermally diffuse is a time required for heat generated by irradiation with the laser beam 41 to spread outside the beam spot due to heat conduction, and in the first embodiment, the thermal diffusion time td [s] (an elapsed time from the irradiation with the laser beam 41) is represented by:

td=(r2)/4α,

where α [mm2/s] is the thermal diffusivity of the film layer 212, and r [mm] is a beam spot radius that is considered as a thermal diffusion length in plane. For example, when the thermal diffusivity of the film layer is 0.1 mm²/s and the beam spot radius of the pulse laser beam is 0.005 mm, the thermal diffusion time is about 60 μs. In this case, the pulse width of the pulse laser beam is set to be shorter than 60 μs.

In the first embodiment, in the mask forming step 1002, as illustrated in FIG. 7, the laser processing apparatus 1 forms the opening 213 that is a recess at a position overlapping the recessed portion 206 of the device 205 formed in each device region 204 of the film layer 212. Note that in the first embodiment, the opening 213 formed in the film layer 212 is provided with a remaining portion in which the film layer 212 remains at a groove bottom. Thus, in the mask forming step 1002, the opening 213 that is the recess is formed at a position overlapping the recessed portion 206 of the device 205 formed in each device region 204, and the mask 214 used in the etching step 1004 is formed on the film layer 212. The remaining portion has a thickness of, for example, 0.1 μm or more and 1 μm or less.

### Removal Step

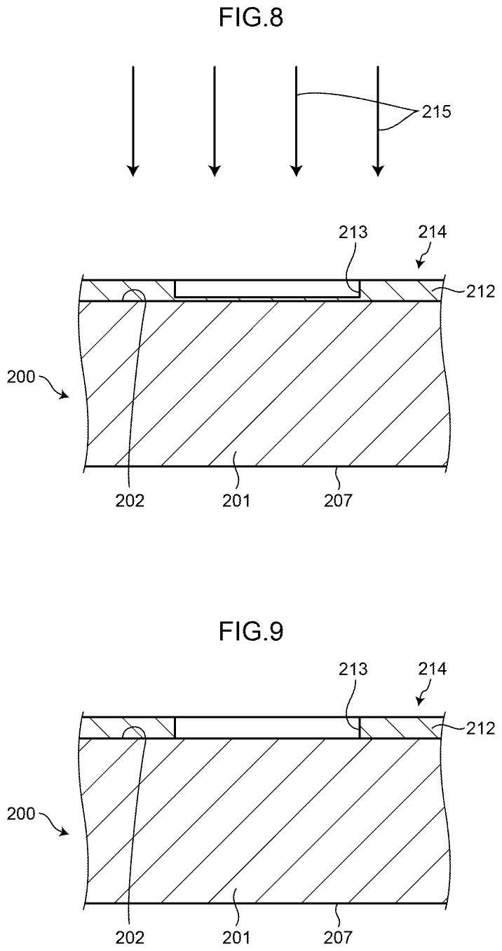

FIG. 8 is an enlarged cross-sectional view illustrating the main part of the workpiece during the removal step of the device chip manufacturing method illustrated in FIG. 4. FIG. 9 is an enlarged cross-sectional view illustrating the main part of the workpiece after the removal step of the device chip manufacturing method illustrated in FIG. 4. The removal step 1003 is a step of removing the film layer 212 remaining at the groove bottom of the opening 213 by ashing before performing the etching step 1004.

In the first embodiment, in the removal step 1003, a plasma device, which is not illustrated, accommodates the workpiece 200 on which the mask 214 is formed, in a chamber, and holds a side of the back surface 207 of the workpiece 200 on a lower electrode. In the first embodiment, in the removal step 1003, the plasma device, which is not illustrated, supplies oxygen, which is an ashing gas, into the chamber while supplying high-frequency power to an upper electrode and the lower electrode, and converts the oxygen into plasma.

In the first embodiment, in the removal step 1003, as illustrated in FIG. 8, the plasma device, which is not illustrated, supplies oxygen 215 converted into plasma toward the front surface 202 of the workpiece 200 to perform ashing for the film layer 212, that is, the mask 214. In the first embodiment, in the removal step 1003, as illustrated in FIG. 9, the remaining portion of the film layer 212 at the groove bottom of the opening 213 of the film layer 212, that is, the mask 214 is removed, and a front surface 202 of the substrate 201 of the workpiece 200 is exposed from the groove bottom of the opening 213.

### Etching Step

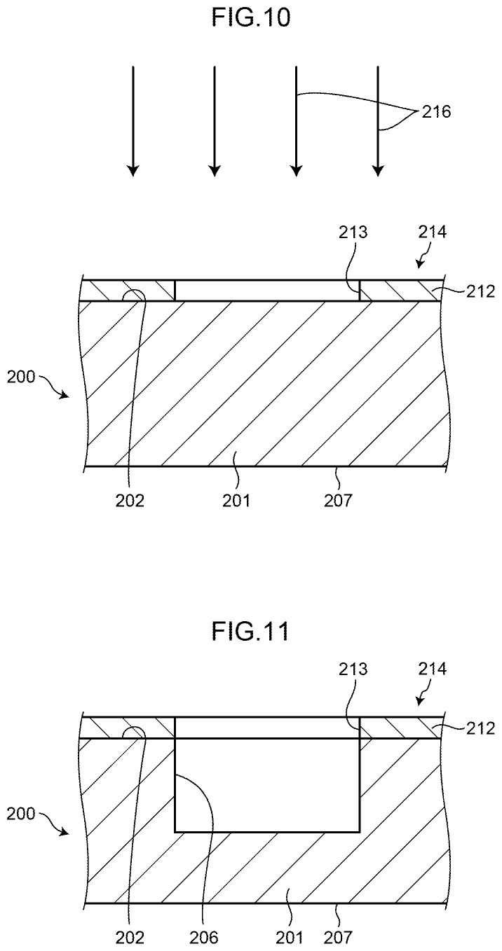

FIG. 10 is an enlarged cross-sectional view illustrating the main part of the workpiece during the etching step of the device chip manufacturing method illustrated in FIG. 4. FIG. 11 is an enlarged cross-sectional view illustrating the main part of the workpiece after the etching step of the device chip manufacturing method illustrated in FIG. 4. The etching step 1004 is a step of etching the workpiece 200 through the mask 214 to form the recessed portion 206 in the device region 204 of the workpiece 200.

In the first embodiment, in the etching step 1004, the plasma device, which is not illustrated, supplies the etching gas into the chamber while supplying high frequency power to the upper electrode and the lower electrode, and converts the etching gas into plasma. For the etching gas, an SF6 gas, a CF4 gas or a C4F8 gas, which is a fluorine-based gas, a mixed gas of a CF4 gas and an Ar gas, a mixed gas of a C4F8 gas and an Ar gas, an oxygen gas, or the like is supplied into the chamber.

In the first embodiment, in the etching step 1004, as illustrated in FIG. 10, the plasma device, which is not illustrated, supplies an etching gas 216 converted into plasma toward the front surface 202 of the workpiece 200, and etches the substrate 201 of the workpiece 200 exposed from the opening 213 of the film layer 212, that is, the mask 214. Furthermore, in the first embodiment, in the etching step 1004, the substrate 201 of the workpiece 200 exposed from the opening 213 is etched by anisotropic etching or a Bosch process for the substrate 201 of the workpiece 200. In the first embodiment, in the etching step 1004, as illustrated in FIG. 11, the substrate 201 of the workpiece 200 at the bottom of the opening 213 is etched to form the recessed portion 206 at a predetermined depth at the bottom of the opening 213, that is, in the device region 204.

Note that the film layer forming step 1001, the mask forming step 1002, the removal step, and the etching step 1004, which are described above, constitute the processing method for processing of the workpiece 200. In other words, the processing method includes the film layer forming step 1001, the mask forming step 1002, the removal step 1003, and the etching step 1004. In the processing method of the present disclosure, the film layer 212 may contain the material including an organic substance, and the processing method may include the removal step 1003.

In addition, the device chip manufacturing method according to the first embodiment may not include the removal step 1003. In other words, in the present disclosure, the processing method may include the film layer forming step 1001, the mask forming step 1002, and the etching step 1004 without including the removal step 1003. In this configuration, in the mask forming step 1002, the film layer 212 remains at the groove bottom of the opening 213, and in the etching step 1004, the film layer 212 remaining at the groove bottom of the opening 213 is etched and the workpiece 200 is etched through the mask 214.

### Mask Removing Step

FIG. 12 is a partially cross-sectional side view schematically illustrating the mask removing step of the device chip manufacturing method illustrated in FIG. 4. The mask removing step 1005 is a step of removing the mask 214 from the front surface 202 of the workpiece 200.

In the first embodiment, in the mask removing step 1005, the laser processing apparatus 1 holds the back surface 207 of the workpiece 200 on the spinner table 13 of the coating/cleaning unit 10 in the suction manner, and clamps the frame 210 with the clampers 17. In the first embodiment, in the mask removing step 1005, as illustrated in FIG. 12, the laser processing apparatus 1 applies the cleaner 19 from an end of the cleaning nozzle 15 to the center of the front surface 202 of the workpiece 200 while rotating the spinner table 13 of the coating/cleaning unit 10 about the axis, and removes the film layer 212, that is, the mask 214, from the front surface 202 of the workpiece 200 to clean the front surface 202 of the workpiece 200.

### Device Forming Step

FIG. 13 is a perspective view schematically illustrating the workpiece after the device forming step of the device chip manufacturing method illustrated in FIG. 4. The device forming step 1006 is a step of forming the device 205 in the device region 204 of the workpiece 200 from which the mask 214 has been removed. In the first embodiment, in the device forming step 1006, as illustrated in FIG. 13, the device 205 is formed in the device region 204 of the workpiece 200. In the first embodiment, in the device forming step 1006, the device 205 having the trench structure in which the recessed portion 206 serves as the trench is formed in the device region 204.

### Division Step

FIG. 14 is a perspective view schematically illustrating the workpiece after the division step of the device chip manufacturing method illustrated in FIG. 4. The division step 1007 is a step of dividing the workpiece 200 along the planned division lines 203 to form the device chips 220 after the device forming step 1006.

In the first embodiment, in the division step 1007, as illustrated in FIG. 14, the workpiece 200 is divided along the planned division lines 203 by using the laser processing apparatus or a cutting device, and the workpiece 200 is divided into the individual device chips 220. In the present disclosure, in the division step 1007, after a division starting point such as a modified layer or a half-cut groove is formed along each of the planned division lines 203, the workpiece 200 may be divided by grinding the back surface 207. Furthermore, in the present disclosure, in the division step 1007, a division starting point may be formed while the workpiece 200 is fixed on a sheet so that the sheet is stretched to divide the workpiece 200 into individual device chips 220.

As described above, in the laser processing apparatus 1 and the device chip manufacturing method according to the first embodiment, the laser beam 41 with which the film layer 212 is irradiated has transparency to the substrate 201 of the workpiece 200 and has an extremely small light absorption rate, and therefore, when the opening 213 is formed in the film layer 212 and the mask 214 is formed, the workpiece 200 is prevented from being processed.

Furthermore, in the laser processing apparatus 1 and the device chip manufacturing method according to the first embodiment, the wavelength of the laser beam 41 with which the film layer 212 is irradiated is a wavelength that resonates with the material constituting the film layer 212. Therefore, the processing of the film layer 212 is promoted by the resonance, enabling reduction of a processing time of forming the mask 214.

Therefore, the laser processing apparatus 1 and the device chip manufacturing method according to the first embodiment have the effects of preventing the workpiece 200 from being processed during emission of the laser beam 41 when the mask 214 is formed, and reducing the processing time.

### Second Embodiment

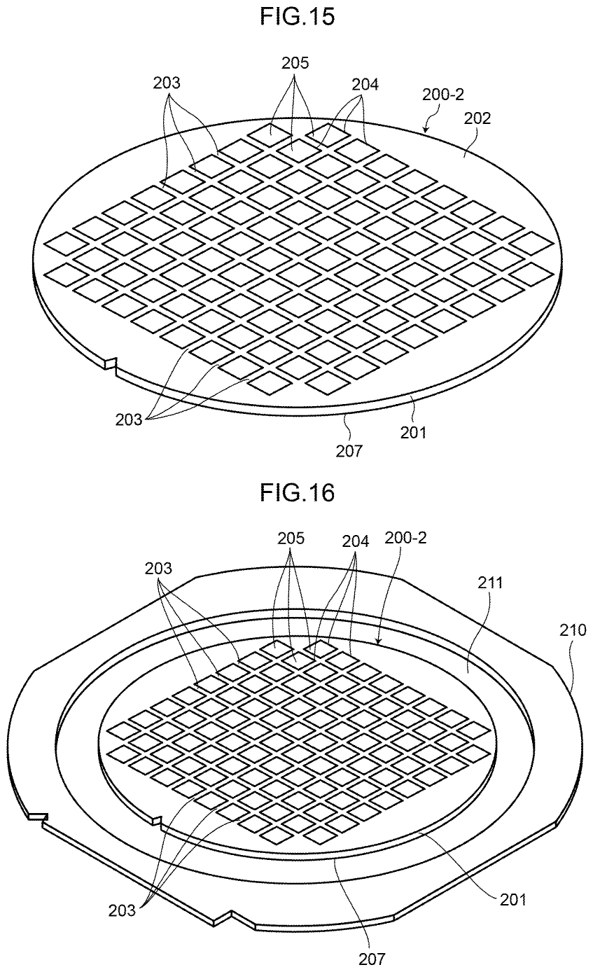

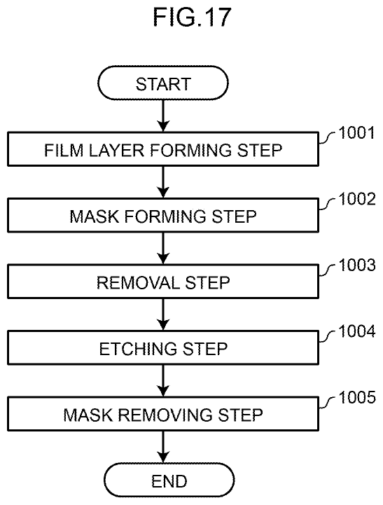

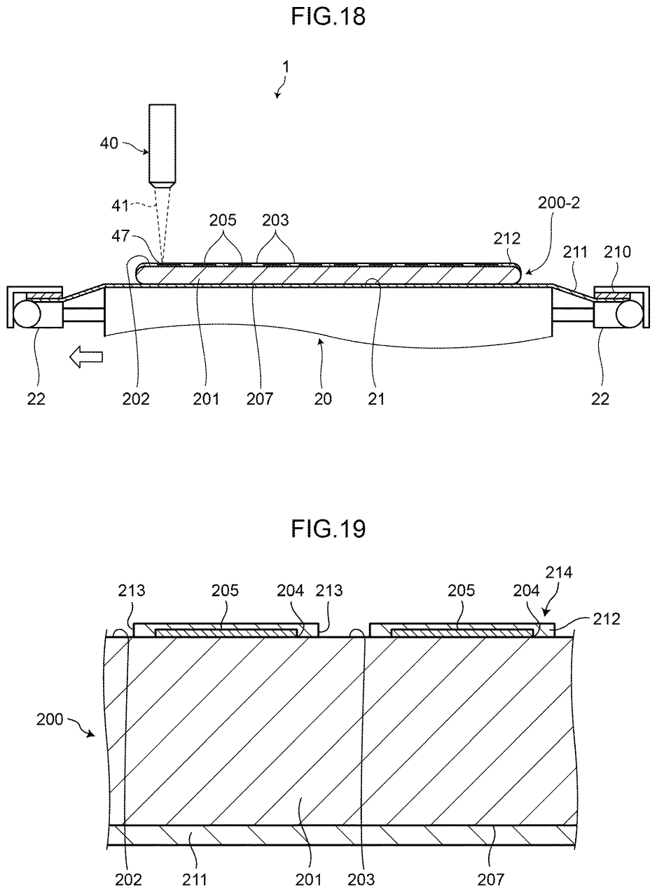

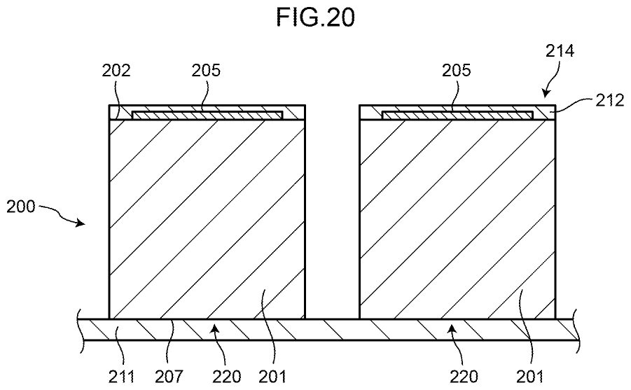

The laser processing apparatus and a device chip manufacturing method according to a second embodiment will be described with reference to the drawings. FIG. 15 is a perspective view schematically illustrating a workpiece to be processed by the laser processing apparatus and the device chip manufacturing method according to the second embodiment. FIG. 16 is a perspective view schematically illustrating a state of the workpiece illustrated in FIG. 15, supported by the frame. FIG. 17 is a flowchart illustrating a procedure of the device chip manufacturing method according to the second embodiment. FIG. 18 is a partially cross-sectional side view schematically illustrating the mask forming step of the device chip manufacturing method illustrated in FIG. 17. FIG. 19 is an enlarged cross-sectional view illustrating a main part of the workpiece after the removal step of the device chip manufacturing method illustrated in FIG. 17. FIG. 20 is an enlarged cross-sectional view illustrating a main part of the workpiece after the etching step of the device chip manufacturing method illustrated in FIG. 17. In FIGS. 16, 17, 18, 19, and 20, the same portions as those in the first embodiment are denoted by the same reference numerals, and description thereof is not repeated.

The workpiece 200-2 to be processed by the laser processing apparatus 1 and the device chip manufacturing method according to the second embodiment is the same as the workpiece 200 in the first embodiment, except that the device 205 is formed in the device region 204 as illustrated in FIGS. 15 and 16. In other words, as illustrated in FIGS. 15 and 16, the workpiece 200-2 to be processed by the laser processing apparatus 1 and the device chip manufacturing method according to the second embodiment is configured so that the plurality of planned division lines 203 are set and the device 205 is formed in each of the device regions 204 defined by the planned division lines 203.

The device chip manufacturing method according to the second embodiment is a method of dividing the workpiece 200-2 along the planned division lines 203 and dividing the workpiece 200-2 into individual device chips 220. As illustrated in FIG. 17, the device chip manufacturing method according to the second embodiment includes the film layer forming step 1001, the mask forming step 1002, the removal step 1003, the etching step 1004, and the mask removing step 1005.

In the second embodiment, in the film layer forming step 1001, the laser processing apparatus 1 forms the film layer 212 over the entire front surface 202 of the workpiece 200-2 illustrated in FIGS. 15 and 16 by the coating/cleaning unit 10, as in the first embodiment.

In the second embodiment, in the mask forming step 1002, the laser processing apparatus 1 irradiates the film layer 212 with the laser beam 41 along the planned division lines 203 while relatively moving the laser beam irradiation unit 40 and the workpiece 200-2 along the planned division lines 203, as illustrated in FIG. 18. In the second embodiment, in the mask forming step 1002, the laser processing apparatus 1 irradiates a position overlapping each of the planned division lines 203 of the film layer 212 with the laser beam 41 to form the opening 213 at the position overlapping the planned division line 203 of the film layer 212. In this way, in the second embodiment, in the mask forming step 1002, the opening 213 is formed in the film layer 212 along the planned division line 203.

In the second embodiment, in the removal step 1003 the film layer 212 at the groove bottom of the opening 213 is removed, as in the first embodiment, and as illustrated in FIG. 19, the device 205 is covered with the film layer 212 and the mask 214 is formed to expose the planned division line 203.

In the second embodiment, in the etching step 1004, the plasma device, which is not illustrated, etches the workpiece 200-2 along the planned division line 203 through the mask 214. In the second embodiment, in the etching step 1004, the plasma device etches the planned division line 203 exposed from the bottom of the opening 213 of the film layer 212 and mask 214, etches the entire planned division line 203 exposed from the opening 213 in the thickness direction, and divides the workpiece 200 into the device chips 220, as illustrated in FIG. 20.

Thus, in the second embodiment, the etching step 1004 also serves as the division step 1007 of dividing the workpiece 200 along the planned division lines 203 to form the device chips 220. Note that in the second embodiment, as in the first embodiment, the film layer 212 at the groove bottom of the opening 213 may be etched in the etching step 1004 without performing the removal step 1003.

In the second embodiment, in the mask removing step 1005, the mask 214 is removed from the front surface 202 of the workpiece 200, as in the first embodiment.

The laser beam 41 applied to the film layer 212 has transparency to the substrate 201 of the workpiece 200-2 and the laser beam 41 has a wavelength resonating with the material constituting the film layer 212, and therefore, the laser processing apparatus 1 and the device chip manufacturing method according to the second embodiment have the effects of preventing the workpiece 200-2 from being processed during emission of the laser beam 41, and reducing the processing time, as in the first embodiment. In addition, suppression of light absorption by the workpiece 200-2 during emission of the laser beam 41 has effects of enabling suppression of temperature rise in each of the device chips 220 due to the laser beam 41, and improvement of die strength of the device chip 220.

According to the present disclosure, it is possible to prevent the workpiece from being processed during irradiation with light and reduce a processing time.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A method for processing a workpiece, the method comprising:
forming a film layer on a workpiece;
forming a mask by irradiating the film layer with light having a wavelength such that the light passes through the workpiece and resonates with a material constituting the film layer to form an opening in the film layer; and
etching the workpiece through the mask.

2. The method according to claim 1, wherein
the light to form the mask is a pulse laser beam, and
the pulse laser beam has a pulse width that is set shorter than a time required for one pulse of the pulse laser beam with which the film layer is irradiated to thermally diffuse outside of a beam spot of the pulse laser beam on the film layer.

3. The method according to claim 1, wherein the light has a wavelength that resonates with molecular vibration of the material or electron transition between energy levels of the material.

4. The method according to claim 1, wherein
the forming of the mask includes making the film layer remain at a groove bottom of the opening, and
the etching includes etching the film layer remaining at the groove bottom of the opening, and etching a workpiece through the mask.

5. The method according to claim 1, wherein
the film layer includes an organic material, and
the method further comprises removing the film layer remaining at the groove bottom of the opening by ashing before the etching.

6. The method according to claim 3, wherein
the film layer is made of a water-soluble resin, and
the molecular vibration is stretching vibration of OH group of the water-soluble resin.

7. The method according to claim 3, wherein
the film layer includes an organic material, and
the molecular vibration is stretching vibration of CH group of the organic material.

8. A method for manufacturing a device chip, the method comprising:
forming a film layer on a wafer on which a plurality of lines to be divided and a plurality of device regions defined by the lines to be divided are set;
forming a mask by irradiating the film layer with light having a wavelength such that the light passes through the wafer and resonates with a material constituting the film layer to form an opening in the film layer;
etching the wafer through the mask;
removing the mask from the wafer; and
dividing the wafer along the lines to be divided to form device chips.

9. The method according to claim 8, wherein
the forming of the mask includes irradiating the film layer corresponding to the device regions with the light,
the etching includes forming a recessed portion in each of the device regions of the wafer,
the method further comprises forming a device in the device region of the wafer from which the mask is removed after the removing of the mask, and
the dividing to form the device chips is performed after the forming of the device.

10. The method according to claim 8, wherein
the forming of the mask includes forming a mask by irradiating the film layer with the light along each of the lines to be divided to form an opening in the film layer along the line to be divided, and
the etching includes etching the wafer through the mask along the lines to be divided.

11. The method according to claim 8, wherein
the light to form the mask is a pulse laser beam, and
the pulse laser beam has a pulse width that is set shorter than a time required for one pulse of the pulse laser beam with which the film layer is irradiated to thermally diffuse outside of a beam spot of the pulse laser beam on the film layer.

12. The method according to claim 8, wherein the light has a wavelength that resonates with molecular vibration of the material or electron transition between energy levels of the material.

13. The method according to claim 10, wherein the etching also serves as the dividing.

14. A laser processing apparatus to process a film layer of a workpiece on which the film layer is stacked, the laser processing apparatus comprising:
a holding unit configured to hold the workpiece on which the film layer is stacked;
an oscillator;
a condenser configured to focus a laser beam emitted from the oscillator on the film layer stacked on the workpiece held by the holding unit; and
a moving unit configured to move a focal point where the laser beam is focused on the workpiece by the condenser relative to the workpiece held by the holding unit,
wherein a wavelength of the laser beam focused on the film layer by the condenser is a wavelength such that the laser beam passes through the workpiece and resonates with a material constituting the film layer.

15. The laser processing apparatus according to claim 14, wherein
the laser beam is a pulse laser beam, and
the pulse laser beam has a pulse width that is set shorter than a time required for one pulse of the pulse laser beam with which the film layer is irradiated to thermally diffuse outside of a beam spot of the pulse laser beam on the film layer.

16. The laser processing apparatus according to claim 14, wherein the laser beam focused on the film layer by the condenser has a wavelength that resonates with molecular vibration of the material or electron transition between energy levels of the material.

17. The laser processing apparatus according to claim 14, further comprising a wavelength conversion unit configured to convert the wavelength of the laser beam emitted from the oscillator,
wherein the condenser is configured to focus the laser beam whose wavelength has been converted by the wavelength conversion unit, on the film layer.
